(19) United States
(12) Patent Application Publication
(10) Pub. No.: US 2006/0103025 A1
(43) Pub. Date: May 18, 2006

(54) Semiconductor device including sealing ring

(75) Inventors: Takeshi Furusawa, Chiyoda-ku (JP); Masahiro Matsumoto, Chiyoda-ku (JP); Noboru Morimoto, Chiyoda-ku (JP); Masazumi Matsuura, Chiyoda-ku (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: Renesas Technology Corp., Chiyoda-ku (JP)

(21) Appl. No.: 11/271,811

(22) Filed: Nov. 14, 2005

(30) Foreign Application Priority Data
Nov. 15, 2004 (JP) 2004-330698

(51) Int. Cl. H01L 23/52

(52) U.S. Cl. 257/758

(57) ABSTRACT

A semiconductor device includes a low dielectric constant film having a copper interconnection formed therein, a silicon oxide film arranged above the low dielectric constant film, a surface protection film arranged above the silicon oxide film, a sealing ring formed to surround a circuit forming region, and a groove portion formed outside the sealing ring when viewed two-dimensionally. The groove portion is formed such that its bottom portion is located above the low dielectric constant film and such that the bottom portion is located below an upper end of the copper interconnection.

### BACKGROUND OF THE INVENTION

1. Field of the Invention

The present invention relates to a semiconductor device.

2. Description of the Background Art

As a semiconductor device is reduced in size, a parasitic capacitance of a copper interconnection becomes substantially equal to a capacitance of an input/output of a transistor itself, which hinders an operation at higher speed of an element. Accordingly, adoption of an insulating film having a relative dielectric constant smaller than conventional silicon oxide (SiO₂; relative dielectric constant k≈4) has increasingly been studied. An insulating film of an organic silica glass (SiOC) type containing carbon and hydrogen in silicon oxide is mainly used as an insulating film having a small relative dielectric constant. The insulating film of organic silica glass type has a relative dielectric constant of approximately 3.3 or smaller, and it is assumed in the present invention that a film having a relative dielectric constant of 3.3 or smaller is referred to as a low dielectric constant film.

In some semiconductor devices, a protective pattern called a sealing ring (or “guard ring”) is formed in a peripheral portion, in order to prevent degradation of an operation characteristic of a device caused by entry of water from a side surface. The sealing ring is formed to surround a circuit forming region where an electric circuit is formed.

The sealing ring is implemented in such a manner that metal portions such as an interlayer connection portion connecting, for example, contacts, interconnections and insulating films are stacked, and formed to penetrate the insulating film. When viewed in a cross-section, these metal portions extend in a direction substantially perpendicular to the substrate, so as to form a protection wall against water. The sealing ring is formed like an enclosing line when viewed two-dimensionally.

The low dielectric constant film has mechanical strength lower than a silicon oxide film. For example, using a Young's modulus as an index for the mechanical strength, silicon oxide has a Young's modulus of approximately 75 GPa, while a material of organic silica glass type has a Young's modulus of at least approximately 10 GPa to at most approximately 25 GPa. A more porous low dielectric constant film for achieving further smaller dielectric constant has a smaller Young's modulus;

In some semiconductor devices in which a low dielectric constant film is adopted, the low dielectric constant film is formed above the substrate, and an insulating film having a Young's modulus larger than the low dielectric constant film is formed above the low dielectric constant film. Such a semiconductor device suffers from tendency of delamination of the low dielectric constant film in the dicing step in which a semiconductor wafer on which a plurality of semiconductor devices are formed is divided into chips. If the low dielectric constant film delaminates in the dicing step, delamination reaches the sealing ring and the sealing ring is broken. If the sealing ring is broken, water enters the circuit forming region, which adversely affects an operation of the device.

Japanese Patent Laying-Open No. 2004-172169 discloses a semiconductor device in which a reinforcement pattern for suppressing occurrence of delamination of an interlayer film is arranged in a peripheral portion of an LSI (Large Scale Integration) adopting a low dielectric constant film as the interlayer film. The reinforcement pattern is such that a pattern of a plurality of dummy interconnections is formed. Alternatively, the reinforcement pattern is such that a groove having a depth reaching at least the interlayer film under the low dielectric constant film is formed. According to the disclosure, development of delamination of the interlayer film can be stopped by forming such a reinforcement pattern.

Japanese Patent Laying-Open No. 2004-193382 discloses a semiconductor chip in which an isolation groove is formed between a portion of an insulating film on an element forming region and a portion above a dicing lane region. The isolation groove is formed to completely surround a perimeter of the element forming region so as to separate the element forming region from the dicing lane region. Namely, the isolation groove is formed to reach the surface of the substrate, in a manner completely dividing the insulating film. According to the disclosure, with such a structure, film delamination in the dicing step can be prevented even when a low dielectric constant film having poorer mechanical strength and adhesion strength is employed.

Delamination of the insulating film in the dicing step is disadvantageous not only in the low dielectric constant film but also in a BPSG (Boron-doped Phospho Silicate Glass) film having mechanical strength lower than silicon oxide or in a silicon nitride film that has high membrane stress and tends to readily delaminate.

For example, Japanese Patent Laying-Open No. 09-045766 discloses a semiconductor integrated circuit device in which a bottom portion of a slit reaching a position deeper than at least an interface between an interlayer insulating film and a BPSG film below the same is formed outside a guard ring. According to the disclosure, in such a semiconductor integrated circuit device, the slit can prevent a crack, that has occurred at the interface between the BPSG film containing boron in high concentration and the interlayer insulating film, from developing along the interface toward inside the chip.

Moreover, Japanese Patent Laying-Open No. 2004-079596 discloses a semiconductor device in which an opening reaching an interlayer insulating film is formed in a passivation film. The opening is arranged to surround a sealing ring. According to the disclosure, in such a semiconductor device, an upper surface of an interconnection layer is not exposed to outside air and lowering in an effect to protect the semiconductor device with the sealing ring can be prevented. Further according to the disclosure, stress caused when a dicing region is diced is less likely to transmit to the passivation film above the circuit forming region, and a crack in the passivation film above the circuit forming region can be prevented.

If a structure for physically dividing the film by forming a groove completely dividing the film which may delaminate is adopted according to Japanese Patent Laying-Open No. 2004-172169, development of delamination can be stopped at this groove. If this structure is adopted in the semiconductor device including the low dielectric constant film, however, the following problem is caused.

Initially, as etching depth is great, productivity is lowered. In many cases, a semiconductor device includes multi-layer interconnections, and the low dielectric constant film is formed in a lower portion where an interval between interconnections is narrow (a portion closer to the substrate). Therefore, in order to form a groove physically dividing and cutting the low dielectric constant film, all of the surface protection film, an upper interconnection interlayer film and a lower interconnection interlayer film (low dielectric constant film) should be etched. For example, when seven to nine layers are etched, the total thickness of the layers attains to approximately 6 to 10 μm, which results in longer time for a normal etching process.

Secondly, as a high selective etching ratio with regard to a resist cannot be set, productivity is lowered. As the low dielectric constant film of organic silica glass type contains carbon and hydrogen, a high selective etching ratio between the low dielectric constant film and the resist ((etching rate of the low dielectric constant film)/(etching rate of the resist)) cannot be set. In addition, as a silicon nitride film or a silicon carbonitride film covering a copper interconnection in each layer also contains nitrogen or carbon, a selective etching ratio is small. Therefore, the resist becomes thinner before etching of the low dielectric constant film is completed, and a measure such as application of the resist twice has been necessary.

Moreover, the step of removing the resist after etching for dividing the low dielectric constant film is time consuming, which results in lower productivity. The quality of the low dielectric constant film is altered (the low dielectric constant film is oxidized) by oxygen plasma for removing the resist, that is, the low dielectric constant film shrinks, and a crack is more likely. In order to remove the resist while the surface of the low dielectric constant film is exposed, less oxidative low-pressure oxygen plasma or the like should be used. Removal of the resist using the low-pressure oxygen plasma, however, progresses slowly and is time consuming. Meanwhile, if a thick resist is formed in order to form a deep groove, it takes more time in removing the resist.

### SUMMARY OF THE INVENTION

An object of the present invention is to provide a semiconductor device of which productivity is high and in which development of delamination as far as the sealing ring is prevented.

A semiconductor device according to one aspect of the present invention includes: a substrate; a low dielectric constant film arranged above the substrate and having a first copper interconnection formed therein; an interlayer insulating film arranged above the low dielectric constant film; a surface protection film arranged above the interlayer insulating film; a sealing ring formed to surround a circuit forming region; and a recessed portion formed outside the sealing ring when viewed two-dimensionally. At least one layer in the interlayer insulating film includes a second copper interconnection therein. At least one layer in the interlayer insulating film and the surface protection film has a Young's modulus larger than the low dielectric constant film. The recessed portion includes at least one of a groove portion and a cut portion. The recessed portion is formed such that its bottom portion is located above the low dielectric constant film, and such that the bottom portion is located below an upper end of uppermost second copper interconnection.

A semiconductor device according to another aspect of the present invention includes: a substrate; a low dielectric constant film arranged above the substrate; an interlayer insulating film arranged above the low dielectric constant film; a surface protection film arranged above the interlayer insulating film; a sealing ring formed to surround a circuit forming region; and a recessed portion formed outside the sealing ring when viewed two-dimensionally. At least one layer in the interlayer insulating film and the surface protection film has a Young's modulus larger than the low dielectric constant film. The recessed portion includes at least one of a groove portion and a cut portion, and the recessed portion is formed to have a depth below the surface protection film and formed such that its bottom portion is located at a depth between the surface protection film and the low dielectric constant film.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a first schematic cross-sectional view of an end portion of a semiconductor device according to a first embodiment.

FIG. 2 is a second schematic cross-sectional view of the end portion of the semiconductor device according to the first embodiment.

FIG. 3 is a schematic cross-sectional view of the end portion of the semiconductor device for illustrating development of delamination of an insulating film.

FIG. 4 is a schematic cross-sectional view for illustrating an effect of the semiconductor device according to the first embodiment.

FIG. 5 is a first schematic cross-sectional view for illustrating a dicing step in a method of manufacturing the semiconductor device according to the first embodiment.

FIG. 6 is a second schematic cross-sectional view for illustrating the dicing step in the method of manufacturing the semiconductor device according to the first embodiment.

FIG. 7 is a graph illustrating an effect when a depth of a recessed portion is varied according to the present invention.

FIG. 8 is a schematic cross-sectional view of the end portion for illustrating a dimension of the semiconductor device according to the first embodiment.

FIG. 9 is a schematic cross-sectional view of an end portion of a first semiconductor device according to a second embodiment.

FIG. 10 is a schematic cross-sectional view of an end portion of a second semiconductor device according to the second embodiment.

FIG. 11 is a schematic cross-sectional view of an end portion of a third semiconductor device according to the second embodiment.

FIG. 12 is a schematic cross-sectional view for illustrating a dicing step in a method of manufacturing the first semiconductor device according to the second embodiment.

FIG. 13 is a schematic cross-sectional view for illustrating a dicing step in a method of manufacturing the second semiconductor device according to the second embodiment.

FIG. 14 is a first schematic cross-sectional view of an end portion of a semiconductor device according to a third embodiment.

FIG. 15 is a second schematic cross-sectional view of the end portion of the semiconductor device according to the third embodiment.

FIG. 16 is a schematic cross-sectional view for illustrating a function of the semiconductor device according to the third embodiment.

FIG. 17 is a first schematic cross-sectional view for illustrating a dicing step in a method of manufacturing the semiconductor device according to the third embodiment.

FIG. 18 is a second schematic cross-sectional view for illustrating the dicing step in the method of manufacturing the semiconductor device according to the third embodiment.

FIG. 19 is a schematic cross-sectional view of the end portion for illustrating a dimension of the semiconductor device according to the third embodiment.

FIG. 20 is a schematic cross-sectional view of a chip corner portion of a first semiconductor device according to a fourth embodiment.

FIG. 21 is a schematic cross-sectional view of a chip corner portion of a second semiconductor device according to the fourth embodiment.

FIG. 22 is a schematic cross-sectional view of a chip corner portion of a third semiconductor device according to the fourth embodiment.

FIG. 23 is a schematic cross-sectional view for illustrating a dicing step in a method of manufacturing the first semiconductor device according to the fourth embodiment.

FIG. 24 is a schematic cross-sectional view for illustrating a dicing step in a method of manufacturing the second semiconductor device according to the fourth embodiment.

FIG. 25 is a schematic cross-sectional view for illustrating a dicing step in a method of manufacturing the third semiconductor device according to the fourth embodiment.

### DESCRIPTION OF THE PREFERRED EMBODIMENTS

### First Embodiment

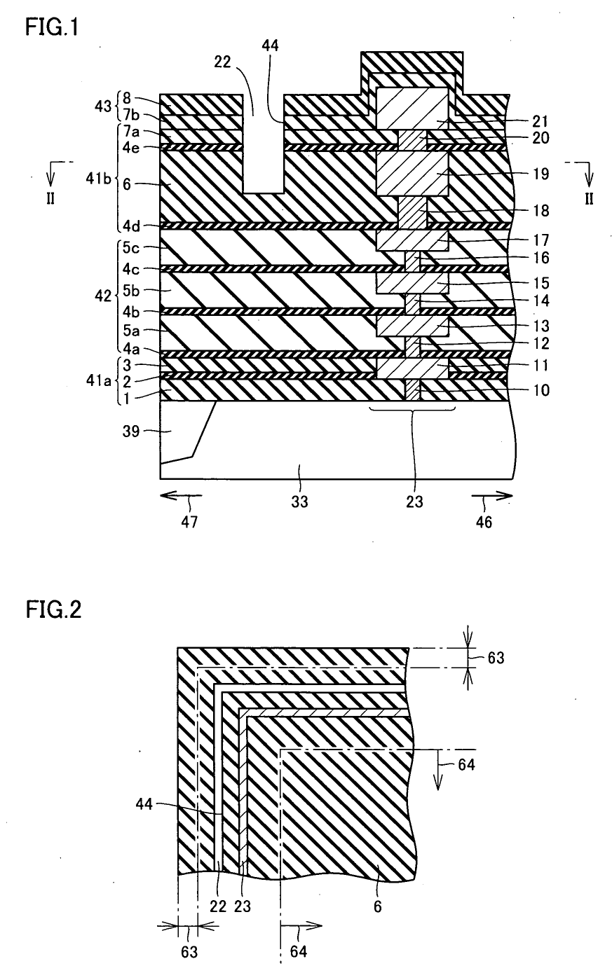

Referring to FIGS. 1 to 8, a semiconductor device according to the first embodiment of the present invention will be described.

FIG. 1 shows a schematic cross-sectional view of an end portion of the semiconductor device according to the present embodiment. The semiconductor device in the present embodiment represents a semiconductor chip. FIG. 1 is a schematic cross-sectional view of a chip corner portion. In FIG. 1, an arrow 47 shows an outer side of the semiconductor device, while an arrow 46 shows an inner side of the same. A circuit forming region is arranged on a side shown with arrow 46.

In the semiconductor device according to the present embodiment, a stack structure 41a including a plurality of interlayer insulating films is formed on an upper surface of a silicon substrate 33. A stack structure 42 including a plurality of interlayer insulating films formed from a material having low dielectric constant is formed on an upper surface of stack structure 41a. A stack structure 41b including a plurality of interlayer insulating films is formed on an upper surface of stack structure 42 including the low dielectric constant film. A surface protection film 43 is formed on an upper surface of stack structure 41b. Surface protection film 43 is also referred to as a passivation film, and formed in order to prevent entry of water through the surface of the semiconductor device. A single-layer silicon nitride film or a stack structure including a silicon nitride film through which entry of water is less likely is normally formed as the surface protection film.

In the present embodiment, stack structure 41a is implemented by stacking a silicon oxide film 1, a silicon carbonitride film 2 and a silicon oxide film 3 in this order. Stack structure 42 is implemented by stacking a silicon carbonitride film 4a, a low dielectric constant film 5a, a silicon carbonitride film 4b, a low dielectric constant film 5b, a silicon carbonitride film 4c, and a low dielectric constant film 5c in this order. Stack structure 41b is implemented by stacking a silicon carbonitride film 4d, a silicon oxide film 6, a silicon carbonitride film 4e, and a silicon oxide film 7a in this order. Silicon carbonitride films 2 and 4a to 4e are each formed as an etching stopper film between insulating films. Surface protection film 43 is implemented by stacking a silicon oxide film 7b and a silicon nitride film 8 in this order.

In the semiconductor device according to the present embodiment, an insulating film of organic silica glass type having a relative dielectric constant of at most 3.3 is formed as low dielectric constant films 5a to 5c. Low dielectric constant films 5a to 5c in the present embodiment have a Young's modulus of 25 GPa or smaller, while silicon oxide films 6, 7a and 7b have a Young's modulus of 75 GPa. In this manner, in the present embodiment, an interlayer insulating film having mechanical strength (Young's modulus) higher than the low dielectric constant film is disposed above the low dielectric constant film.

A sealing ring 23 is formed in a peripheral portion of the semiconductor device. Sealing ring 23 includes a contact 10, copper interconnections 11, 13, 15, 17, and 19, interlayer connection portions 12, 14, 16, 18, and 20, and an aluminum interconnection 21. Copper interconnections 11, 13, 15, 17, and 19 are formed as electric circuit lines in respective layers in the circuit forming region. Copper interconnections 11, 13, 15, 17, and 19 are formed like lines forming a frame in the sealing ring when viewed two-dimensionally.

Interlayer connection portions 12, 14, 16, 18, and 20 are formed in a pattern of holes in the circuit forming region, so as to connect interconnections to each other. Interlayer connection portions 12, 14, 16, 18, and 20 are formed in a pattern of grooves along a direction in which copper interconnections 11, 13, 15, 17, and 19 extend. Interlayer connection portions 12, 14, 16, 18, and 20 are formed to connect copper interconnections 11, 13, 15, 17, and 19 to each another. Contact 10 is arranged between silicon substrate 33 and copper interconnection 11. Contact 10 is in contact with silicon substrate 33.

As described above, the sealing ring in the present embodiment is implemented like a wall in such a manner that the contact, the copper interconnection, the interlayer connection portion, and the aluminum interconnection are aligned in a direction perpendicular to a main surface of the silicon substrate.

In stack structure 42 including the low dielectric constant film, copper interconnections 13, 15 and 17 are formed as first copper interconnections in low dielectric constant films 5a to 5c respectively. Here, one copper interconnection is formed for each low dielectric constant film. In stack structure 41b including the interlayer insulating film, copper interconnection 19 is formed as a second copper interconnection in silicon oxide film 6. In addition, aluminum interconnection 21 is formed under surface protection film 43.

The “copper interconnection” in the present invention includes not only the interconnection formed from copper but also an interconnection formed from an alloy mainly composed of copper and an interconnection having a coating film layer composed of Ta or TaN formed on the surface. For example, the copper interconnection includes an interconnection implemented by coating a bottom surface and a side surface of the interconnection formed from copper with Ta or TaN or a film obtained by stacking layers composed thereof, and an interconnection formed from a copper alloy containing 1% aluminum.

In addition, the “aluminum interconnection” in the present invention includes not only the interconnection formed from aluminum but also an interconnection formed from an alloy mainly composed of aluminum and an interconnection having a coating film layer formed on the surface. For example, the aluminum interconnection includes an interconnection implemented by coating upper and lower surfaces of aluminum alloy containing 1% copper with TiN or Ti.

In the semiconductor device according to the present embodiment, a groove portion 22 serving as a recessed portion is formed outside sealing ring 23. Groove portion 22 is formed such that an inner edge 44 thereof is located outside sealing ring 23. Groove portion 22 extends from the surface of surface protection film 43 toward silicon substrate 33. In the present embodiment, groove portion 22 is formed such that its cross-section is substantially quadrangular. Groove portion 22 is formed to have the flat bottom portion.

Groove portion 22 is formed to a depth below surface protection film 43. Groove portion 22 is formed to penetrate surface protection film 43. In the present embodiment, groove portion 22 is formed such that its bottom portion is lower than an upper end (upper surface) of copper interconnection 19 serving as the uppermost second copper interconnection.

Groove portion 22 is formed such that the bottom portion is located above stack structure 42 including the low dielectric constant film. Groove portion 22 is formed such that the bottom portion is located above any of low dielectric constant films 5a to 5c. Groove portion 22 is formed at a distance from low dielectric constant film 5c. In the present embodiment, a distance between the bottom portion of groove portion 22 and the upper surface of low dielectric constant film 5c is set to at least 10 nm to at most 2 μm.

Groove portion 22 is formed so as not to expose any of low dielectric constant films 5a to 5c. Groove portion 22 is formed such that the bottom portion is located within stack structure 41b including the interlayer insulating film arranged on stack structure 42 including the low dielectric constant film. In the present embodiment, groove portion 22 is formed such that the bottom portion is located within silicon oxide film 6.

FIG. 2 is a schematic cross-sectional view of a chip corner portion of a first semiconductor device according to the present embodiment. FIG. 2 is a cross-sectional view in line II-II in FIG. 1 viewed in a direction of arrow.

A region indicated by an arrow 64 represents the circuit forming region in which an electric circuit is formed. In the present embodiment, a two-dimensional shape of the semiconductor device and a two-dimensional shape of the circuit forming region are both substantially quadrangular. The copper interconnection, the interlayer connection portion, the contact, and the aluminum interconnection included in sealing ring 23 are formed like a line when viewed two-dimensionally. Sealing ring 23 is formed to surround the circuit forming region.

In the present embodiment, groove portion 22 is formed outside sealing ring 23 along the same, and formed to extend substantially in parallel to each other. In particular, groove portion 22 is formed such that inner edge 44 thereof is substantially in parallel to sealing ring 23. Groove portion 22 is formed such that its two-dimensional shape is substantially quadrangular. Groove portion 22 is formed in a shape of a closed frame.

After the semiconductor devices are formed in multiples rows and columns on the surface of the semiconductor wafer, the wafer is divided into individual semiconductor devices as a result of dicing. In the dicing step, a dicing lane serving as a region for dividing the semiconductor wafer is secured. The “dicing lane” refers to a region including a margin for registration in addition to a width across which cutting is actually performed when dicing is performed. The dicing lane of a prescribed width remains in the resultant semiconductor device.

In FIG. 2, the region shown with an arrow 63 represents the dicing lane. Groove portion 22 in the present embodiment is arranged between the dicing lane and sealing ring 23. In addition, groove portion 22 is formed such that inner edge 44 thereof is substantially in parallel to the dicing lane.

In the semiconductor device, the sealing ring is formed like a wall surrounding the circuit forming region, so that entry of water into the circuit forming region can be prevented. When the insulating film delaminates and the delamination reaches the sealing ring in the dicing step for dividing the semiconductor wafer into individual semiconductor devices, however, the sealing ring may be broken. The inventors have studied in detail the delamination of the insulating film in the dicing step, and determined the mechanism as to how delamination occurs as follows.

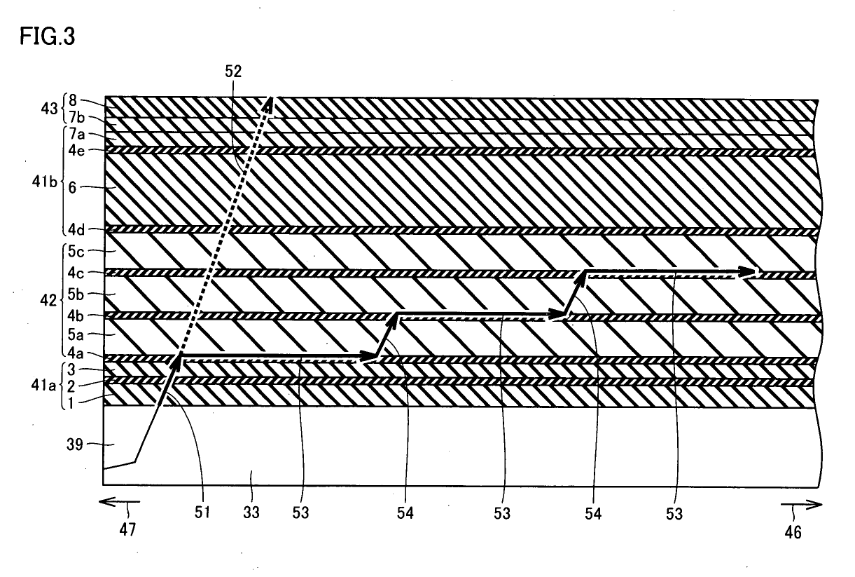

FIG. 3 is a schematic cross-sectional view of the semiconductor device for illustrating development of delamination of the insulating film. FIG. 3 is a schematic cross-sectional view of the end portion of the semiconductor device, without showing the sealing ring.

Delamination of the insulating film originates from chipping 39 of an end surface of silicon substrate 33. Chipping 39 may be caused in the end surface of silicon substrate 33 due to mechanical stress during dicing. Delamination of the insulating film develops from chipping 39. Delamination of the insulating film develops from the lower portion toward the upper portion in terms of an up-down direction. In other words, delamination develops from silicon substrate 33 toward the surface of the semiconductor device.

As shown with an arrow 51, delamination develops upward in stack structure 41a including the interlayer insulating film having adhesion strength stronger than the low dielectric constant film. When the delamination reaches an interface between low dielectric constant film 5a and silicon carbonitride film 4a, the delamination develops in a lateral direction along the interface as shown with an arrow 53, because adhesion strength at the interface is weak. When the delamination develops to some extent in the lateral direction, the delamination then develops to the interface between low dielectric constant film 5b and silicon carbonitride 4b above by one level as shown with an arrow 54. Thereafter, as shown with arrows 53 and 54, delamination develops repeatedly in the lateral direction and to an interface above by one level.

As described above, the delamination of the low dielectric constant film develops toward the circuit forming region in a direction shown with arrow 46. A typical length (depth) of chipping 39 of silicon substrate 33 is at most approximately 5 μm in a direction of width shown in FIG. 3, however, the delamination toward the circuit forming region develops by a distance of not shorter than several tens of μm.

The delamination develops in the lateral direction along the interface of the low dielectric constant film, because silicon oxide films 6, 7a and 7b and silicon nitride film 8 having mechanical strength higher than low dielectric constant films 5a to 5c are formed on the low dielectric constant film. In other words, this is because energy can be released more readily by destroying the interface under the low dielectric constant film having lower adhesion strength and mechanical strength, rather than by destroying a hard film formed in the vicinity of the surface of the semiconductor device.

If the silicon oxide film is arranged instead of the low dielectric constant film or if the insulating film having mechanical strength higher than the low dielectric constant film is not arranged on the low dielectric constant film, the delamination develops upward as shown with an arrow 52, and hardly develops in the lateral direction. For example, if low dielectric constant film 5c serving as the uppermost layer of stack structure 42 is formed and no other upper layer is formed in FIG. 1, delamination hardly develops in the lateral direction but develops toward the surface of the semiconductor device.

As described above, it has been made clear that the delamination of the low dielectric constant film develops in the lateral direction along the surface because the insulating film having a large thickness and high mechanical strength is formed on the low dielectric constant film having low mechanical strength.

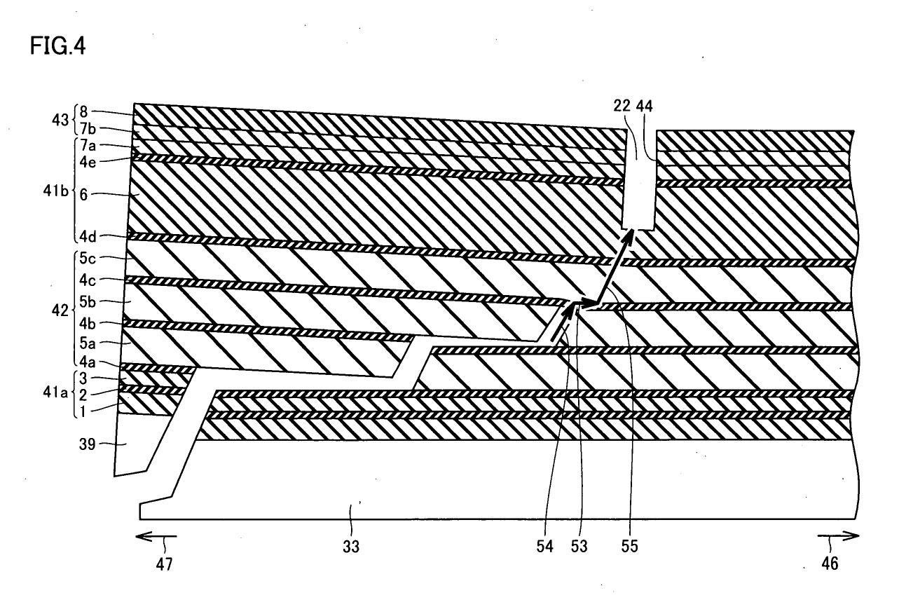

FIG. 4 is a schematic cross-sectional view for illustrating a function of the semiconductor device according to the present embodiment. FIG. 4 is a schematic cross-sectional view of the end portion of the semiconductor device, without showing the sealing ring. In the present embodiment, groove portion 22 serving as the recessed portion is formed to extend from the surface of surface protection film 43 toward silicon substrate 33. In a region where groove portion 22 is formed, stack structure 41b including the interlayer insulating film having mechanical strength higher than low dielectric constant films 5a to 5c can have a smaller thickness. In the present embodiment, groove portion 22 is formed such that its bottom portion is located within silicon oxide film 6, so that silicon oxide film 6 directly under groove portion 22 can have a smaller thickness in the region where groove portion 22 is formed. Therefore, a portion directly under groove portion 22 is more susceptible to breakage.

As shown in FIG. 4, delamination of the low dielectric constant film originating from chipping 39 develops toward the circuit forming region. Silicon oxide film 6 directly under groove portion 22 is thin and susceptible to breakage. In addition, due to delamination of each layer, the insulating film above the delaminated region is bent around an area where groove portion 22 is formed, and stress is concentrated in the region where groove portion 22 is formed. Accordingly, delamination develops upward to groove portion 22 as shown with arrows 53 to 55. Consequently, development of delamination into the region inside groove portion 22 can be suppressed, and occurrence of delamination in the region inside and surrounded by groove portion 22 can be suppressed.

Referring to FIG. 1, as development of delamination into the region inside groove portion 22 can be suppressed, reaching of delamination as far as sealing ring 23 can be suppressed. Consequently, impairment of a function of the sealing ring can be prevented, and entry of water into the semiconductor device can be prevented.

In the semiconductor device according to the present invention, as partial or complete division in a direction of thickness of the low dielectric constant film of which delamination should be suppressed is not necessary, a depth of the recessed portion can be made smaller. Therefore, etching depth for forming the recessed portion is made smaller. Accordingly, a time period required in the etching step can be shortened and productivity is improved.

In addition, as a high selective etching ratio between the low dielectric constant film and the resist cannot be set, for example, it has been necessary to apply the resist twice if the low dielectric constant film is to be divided. In the semiconductor device according to the present embodiment, however, the groove portion has a small depth, and therefore, it is not necessary to apply the resist twice. Moreover, in the semiconductor device according to the present invention, it is not necessary to expose the low dielectric constant film in the surface. Therefore, by adjusting a depth of the groove portion, use of less-oxidative low-pressure oxygen plasma in removing the resist is no longer necessary. Consequently, a time period required for removing the resist in the etching step can further be shortened and productivity is improved.

Referring to FIG. 2, groove portion 22 according to the present embodiment is formed in a shape of a closed frame when viewed two-dimensionally. By adopting such a structure, groove portion 22 can completely surround sealing ring 23, and delamination can be prevented from reaching the sealing ring even if chipping of the substrate in any direction occurs.

In addition, in the present embodiment, groove portion 22 is formed such that the inner edge thereof is arranged between the dicing lane and sealing ring 23 when viewed two-dimensionally. By adopting such a structure, it is ensured that groove portion 22 remains on the surface of the semiconductor device during dicing. For example, if groove portion 22 is arranged in the region of the dicing lane where dicing is actually performed, the groove portion may completely be ground and disappear along with division of the semiconductor wafer. In the present embodiment, such grinding of the groove portion can be prevented, and development of delamination can be suppressed at the groove portion.

Moreover, in the present embodiment, groove portion 22 is formed such that the inner edge thereof is substantially in parallel to the dicing lane when viewed two-dimensionally. By adopting such a structure, development of delamination of the low dielectric constant film can be stopped at a prescribed distance from the dicing lane. Namely, delamination can be suppressed to a length not larger than a prescribed value.

Furthermore, in the present embodiment, groove portion 22 is formed such that the inner edge thereof is substantially in parallel to sealing ring 23 when viewed two-dimensionally. By adopting such a structure, groove portion 22 can be arranged at a prescribed distance from sealing ring 23, and delamination of the low dielectric constant film can be suppressed at a prescribed distance from sealing ring 23. In addition, groove portion 22 is formed along sealing ring 23, so that a region where groove portion 22 is formed can be made smaller.

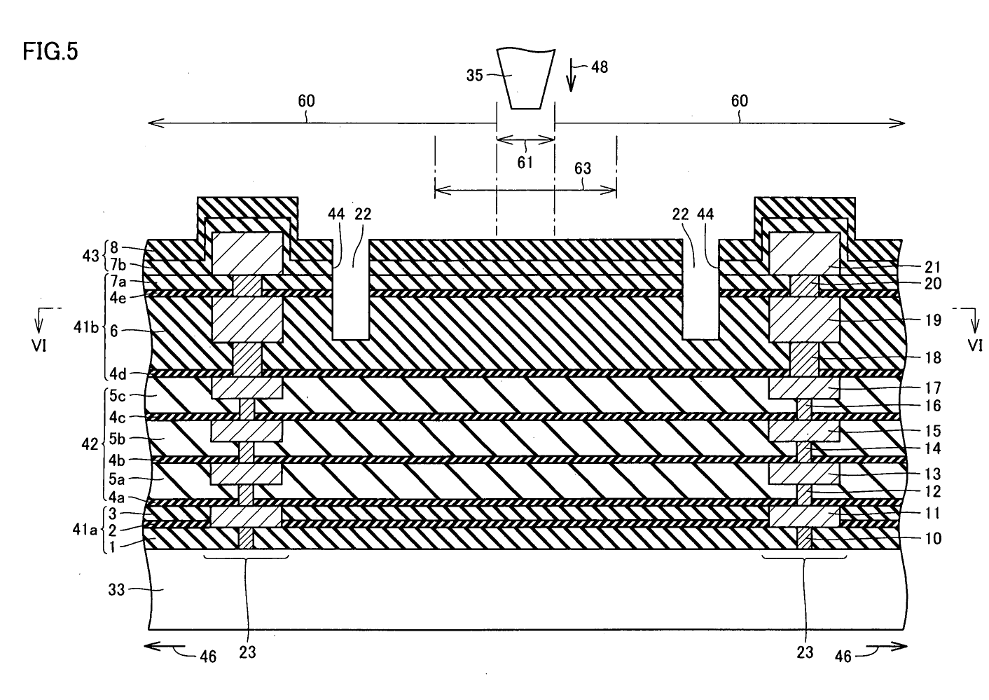

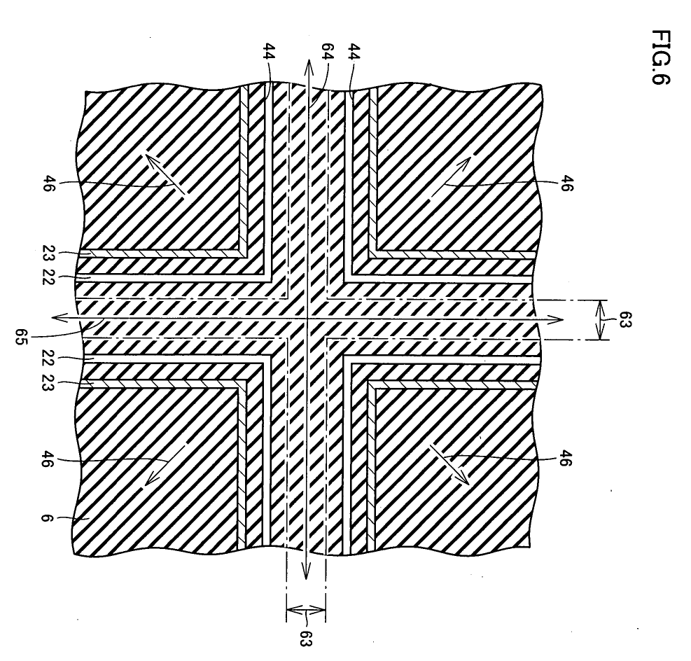

Referring to FIGS. 5 and 6, the dicing step in a method of manufacturing the semiconductor device according to the present embodiment will be described. Silicon substrate 33 is formed, for example, such that its two-dimensional shape is substantially circular. A plurality of semiconductor devices are formed on the surface of silicon substrate 33. In the present embodiment, the semiconductor device is formed such that its two-dimensional shape is substantially quadrangular. The semiconductor devices are formed in rows and columns, and individual semiconductor devices can be obtained by cutting with a dicing blade or the like.

FIG. 5 is an enlarged cross-sectional view of a boundary portion of semiconductor devices adjacent to each other. A stack structure is formed on the surface of silicon substrate 33 with a known method such that an interconnection such as a copper interconnection is included in the insulating film. In addition, an interlayer connection portion is formed so as to connect interconnections to each other. In forming each stack structure, a silicon oxide film, a low dielectric constant film, a surface protection film, and the like are stacked.

Thereafter, groove portion 22 is formed by disposing the resist on the surface of surface protection film 43 followed by etching. Groove portion 22 is formed between sealing ring 23 and the dicing lane region shown with arrow 63. Here, groove portion 22 is formed to penetrate surface protection film 43, to a depth below surface protection film 43. In addition, groove portion 22 is formed so as not to reach stack structure 42 including low dielectric constant films 5a to 5c. A plurality of semiconductor devices including groove portion 22 are formed on the surface of silicon substrate 33.

Thereafter, the dicing step is performed. A dicing blade 35 has a disc-like shape. Dicing blade 35 moves in a direction shown with an arrow 48 while rotating, and carries out cutting. A region shown with an arrow 61 represents a region actually cut by dicing blade 35. Meanwhile, a region shown with arrow 63 represents a dicing lane set as a region where dicing is carried out. A region shown with an arrow 60 represents a semiconductor device region to be formed.

FIG. 6 is a cross-sectional view in line VI-VI in FIG. 5 viewed in a direction of arrow. FIG. 6 is a schematic cross-sectional view of a portion where chip corner portions of four semiconductor devices meet. Arrow 46 shows an inner side of the semiconductor device. In the present embodiment, the semiconductor device is formed such that its two-dimensional shape is substantially quadrangular. The dicing lane shown with arrow 63 is formed like a line when viewed two-dimensionally. The dicing lane is set between the semiconductor devices. Dicing is performed in a direction shown with arrow 64 and in a direction shown with arrow 65. In the corner of the chip corner portion of the semiconductor device to be formed, the dicing blade passes twice.

Individual semiconductor devices can be obtained by thus dividing the silicon substrate including a plurality of semiconductor devices.

A semiconductor device employing low dielectric constant films 5a to 5c of organic silica glass type having a relative dielectric constant k of 2.8 was actually manufactured as a first semiconductor device in the present embodiment, with the manufacturing method above. Low dielectric constant films 5a to 5c have a Young's modulus of 10 GPa. As to the depth of groove portion 22, a distance from low dielectric constant film 5c to the bottom portion of groove portion 22 was set to 1 μm. Dicing was carried out, and delamination of the low dielectric constant film was observed. Then, at worst, development of delamination stopped at the region where the groove portion was formed. There was no example in which the delamination of the low dielectric constant film extended beyond the groove portion and reached the sealing ring. Then, a moisture-resistance reliability test was conducted. There was no abnormality observed in an operation of an electric circuit formed inside the region surrounded by the sealing ring, and excellent operation characteristic was exhibited.

In the semiconductor device according to the present embodiment, low dielectric constant films 5a to 5c were sequentially replaced with low dielectric constant films having relative dielectric constant k of at least 2.3 to at most 3.3, and a test in which the semiconductor device was cut by dicing was conducted. Dicing was carried out, and delamination of the low dielectric constant film was observed. Then, delamination stopped at the region of groove portion 22, with regard to any low dielectric constant film having relative dielectric constant k, and there was no example in which the delamination extended beyond groove portion 22 and reached the sealing ring.

Thereafter, a semiconductor device in which silicon oxide film 6 including uppermost copper interconnection 19 among the copper interconnections was replaced with a silicon oxide film containing fluorine (SiOF) was formed as a second semiconductor device in the present embodiment. The fluorine-containing silicon oxide film has a Young's modulus of 40 GPa. An insulating film of organic silica glass type having relative dielectric constant k of 2.8 was employed as low dielectric constant films 5a to 5c. Dicing was carried out, and delamination of the low dielectric constant film was observed. Then, development of delamination that extended farthest stopped at a position of groove portion 22, and there was no example in which the delamination extended beyond the region where groove portion 22 was formed and developed toward sealing ring 23.

As described above, an effect to prevent development of delamination of the low dielectric constant film (having relative dielectric constant k not larger than 3.3) is significant according to the subject application. This may be because, as relative dielectric constant k is smaller, the low dielectric constant film becomes a more porous insulating film and its mechanical strength is lowered (for example, the Young's modulus becomes smaller).

In addition, in the semiconductor device according to the present embodiment, a test for observing development of delamination when dicing is carried out was conducted with regard to various depths of the groove portion. An insulating film of organic silica glass type having relative dielectric constant k of 2.8 was employed as the low dielectric constant film. A fluorine-containing silicon oxide film was formed as the interlayer insulating film, and a silicon oxide film and a silicon nitride film were formed as the surface protection film above the low dielectric constant film.

FIG. 8 shows a schematic cross-sectional view of the end portion of the semiconductor device. A plurality of low dielectric constant films 36 and silicon carbonitride films 37 are stacked, with an insulating film interposed, on the surface of silicon substrate 33. An interlayer insulating film 38 and surface protection film 43 are formed on the upper surface of this stack structure.

A length from low dielectric constant film 36 to the bottom portion of groove portion 22 is denoted as x1. The total thickness of silicon carbonitride film 37, interlayer insulating film 38 and surface protection film 43 is denoted as y1. Namely, a length from low dielectric constant film 36 to the surface of surface protection film 43 in the region other than the region where groove portion 22 and the sealing ring are formed is denoted as y1. In addition, a length from the end surface of the semiconductor device to inner edge 44 of groove portion 22 is denoted as L1.

In this test, the semiconductor device was formed such that length y1 was set to 3 μm and length L1 was set to 30 μm. The sealing ring was arranged at a position inward by 5 μm from inner edge 44 of groove portion 22. Namely, the sealing ring was arranged at a position inward by 35 μm from the end surface of the semiconductor device. A test for observing a length of development of delamination when dicing is carried out was conducted with regard to various depths of groove portion 22 (various lengths x1).

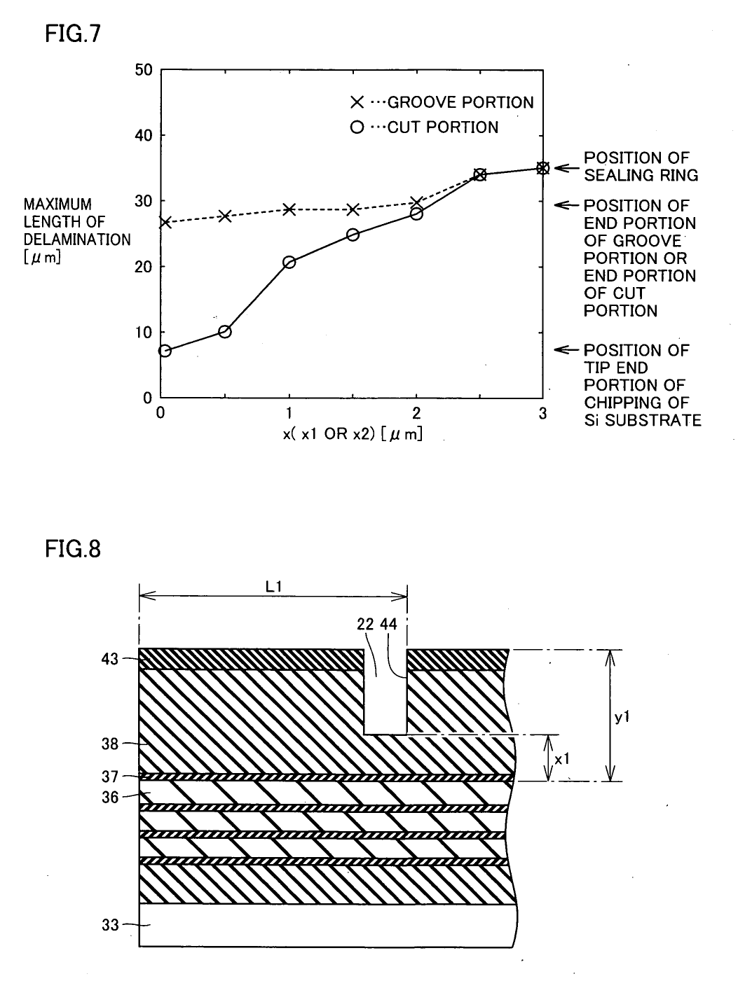

FIG. 7 shows the result of the test. The abscissa represents length x1, while the ordinate represents a maximum length in the lateral direction in which delamination developed. FIG. 7 also shows the result with regard to the semiconductor device according to the third embodiment, which will be described in the third embodiment.

It can be seen that extent of development of delamination is smaller as a distance between the bottom portion of the groove portion and the low dielectric constant film is smaller. When length x1 was set to 3 μm, that is, when the groove portion was not formed, delamination reached the sealing ring and the sealing ring was damaged. When length x1 was set to 2.5 μm, delamination extended beyond the groove portion and reached an area in the vicinity of the sealing ring, although delamination did not reach the sealing ring. When length x1 was set to 2 μm or smaller, development of delamination stopped at the groove portion and did not reach the sealing ring.

As described above, the groove portion is preferably formed such that the distance between the bottom portion and the low dielectric constant film is set to 2 μm or smaller. Alternatively, the bottom portion of the groove portion is preferably located at a depth comparable to ⅔ of length y1 (3 μm). Namely, the groove portion is preferably formed such that a ratio of length x1 to length y1 (x1/y1) is set to ⅔ or smaller. By adopting any of these structures, development of delamination can be stopped at the region where the groove portion is formed, and delamination can be prevented from reaching the sealing ring in a more ensured manner.

From the viewpoint of development of delamination, the distance between the bottom portion of the groove portion and the low dielectric constant film is preferably smaller. If the distance is small, however, the low dielectric constant film may be oxidized by oxygen plasma used for removing the resist in the etching step for forming the groove, as described above. In order to prevent oxidation of the low dielectric constant film, the distance between the bottom portion of the groove portion and the low dielectric constant film is preferably set to 10 nm or larger. In addition, taking into consideration manufacturing error in etching for forming the groove portion, length x1 between the bottom portion of the groove portion and the low dielectric constant film is preferably set to 50 nm or larger.

In the present embodiment, the groove portion serving as the recessed portion is formed. By adopting such a structure, the depth of the bottom portion of the recessed portion can readily be made uniform. When the depth of the recessed portion is uniform, for example, the distance between the low dielectric constant film and the bottom portion of the recessed portion can be made smaller, and it is further ensured that development of delamination of the low dielectric constant film can be suppressed. In order to readily achieve a uniform depth of the groove portion, a width of the groove portion to be formed is preferably set to 20 μm or smaller.

Referring to FIG. 1, in the present embodiment, the bottom portion of the groove portion is formed within silicon oxide film 6, however, the present embodiment is not limited thereto, and groove portion 22 may be formed to penetrate silicon oxide film 6. Alternatively, the bottom portion of groove portion 22 may be located within silicon oxide film 7a. Namely, the bottom portion of groove portion 22 should only be located above the low dielectric constant film.

In addition, in the present embodiment, the groove portion is formed such that its cross-section is substantially quadrangular, however, the present embodiment is not limited thereto and any shape may be adopted. For example, a groove portion having a V-shaped cross-section, i.e., having a pointed bottom may be formed.

### Second Embodiment

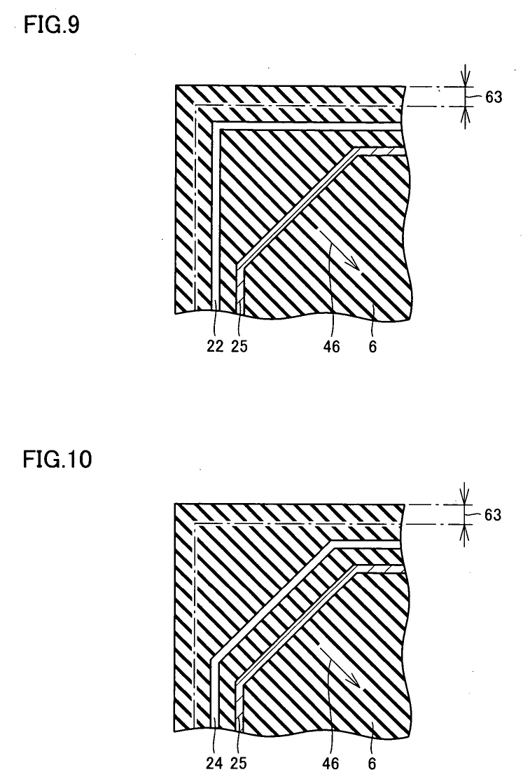

Referring to FIGS. 9 to 13, a semiconductor device according to the second embodiment of the present invention will be described. The semiconductor device in the present embodiment is similar to that in the first embodiment in that the sealing ring is formed to surround the circuit forming region and the groove portion is formed outside the sealing ring. The present embodiment is similar to the first embodiment also in that the semiconductor chip representing the semiconductor device has a substantially quadrangular two-dimensional shape.

FIG. 9 is a schematic cross-sectional view of a chip corner portion of a first semiconductor device according to the present embodiment. In the first semiconductor device, when the chip corner portion is two-dimensionally viewed, a sealing ring 25 has a corner portion beveled. Namely, sealing ring 25 is formed to face the corner in the chip corner portion. Sealing ring 25 is formed in a manner inclined with respect to a perimeter in the chip corner portion. Sealing ring 25 is formed such that its two-dimensional shape is substantially octagonal.

Groove portion 22 is formed in a substantially quadrangular shape so as to conform to the shape of the semiconductor device when viewed two-dimensionally. Groove portion 22 is formed between the dicing lane in the region shown with arrow 63 and sealing ring 25.

FIG. 10 is a schematic cross-sectional view of a chip corner portion of a second semiconductor device according to the present embodiment. In the second semiconductor device, sealing ring 25 and a groove portion 24 have respective corner portions beveled when the chip corner portion is two-dimensionally viewed. Namely, when viewed two-dimensionally, sealing ring 25 and groove portion 24 are formed in a substantially octagonal shape. Sealing ring 25 and groove portion 24 are formed to extend substantially in parallel to each other. Groove portion 24 is formed between the dicing lane and sealing ring 25.

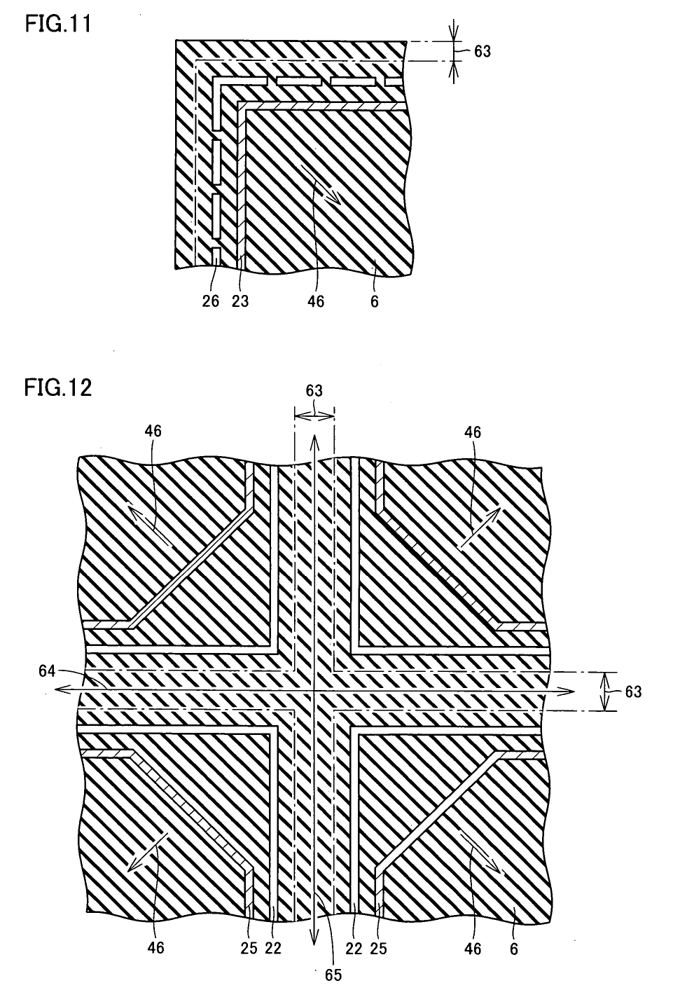

FIG. 11 is a schematic cross-sectional view of a chip corner portion of a third semiconductor device according to the present embodiment. In the third semiconductor device, when viewed two-dimensionally, a sealing ring 23 and a groove portion 26 are formed like a line, and formed such that two-dimensional shape thereof is substantially quadrangular. When viewed two-dimensionally, sealing ring 23 is formed in a shape of a closed frame, whereas groove portion 26 is formed discontinuously. Groove portion 26 is not in a shape of a closed frame, but formed like a dashed line, i.e., discontinuously. Groove portion 26 and sealing ring 23 are formed to extend substantially in parallel to each other. Groove portion 26 is formed between sealing ring 23 and the dicing lane shown with arrow 63.

As the structure is otherwise the same as in the first embodiment, description thereof will not be repeated.

Referring to FIG. 9, in the first semiconductor device in the present embodiment, sealing ring 25 has the corner portion beveled. In the chip corner portion, a distance from the corner to sealing ring 25 is larger.

FIG. 12 shows a schematic cross-sectional view of a semiconductor wafer when dicing is performed in a method of manufacturing the first semiconductor device according to the present embodiment. FIG. 12 is a schematic cross-sectional view of a portion where chip corner portions of four semiconductor devices meet. The region shown with arrow 63 represents the dicing lane, and dicing lanes are orthogonal to each other as in the first embodiment. Dicing is carried out in two directions shown with arrows 64 and 65.

Chipping of the substrate is likely in the chip corner portion, and therefore, delamination of the insulating film is likely in the chip corner portion. When sealing ring 25 has a beveled shape, however, the distance from the corner of the semiconductor device to the sealing ring in the chip corner portion can be made larger, and it is further ensured that delamination can be prevented from reaching the sealing ring.

Referring to FIG. 10, in the second semiconductor device in the present embodiment, not only sealing ring 25 but also groove portion 24 have a beveled shape in the chip corner portion. In the chip corner portion, the distance from the corner to groove portion 24 is made longer.

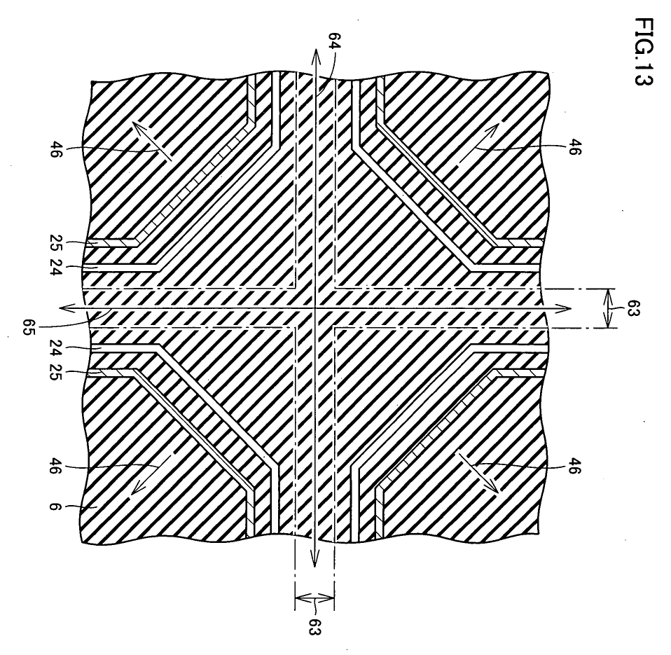

FIG. 13 is a schematic plan view when dicing is performed in a method of manufacturing the second semiconductor device according to the present embodiment. FIG. 13 is a schematic cross-sectional view of a portion where chip corner portions of four semiconductor devices meet. Dicing is carried out in two directions shown with arrows 64 and 65. Dicing is carried out within the dicing lane region shown with arrow 63.

In the second semiconductor device, the distance from the corner of the semiconductor device to groove portion 24 can be made larger in the chip corner portion. Therefore, a larger amount of energy is released until delamination reaches the groove portion, and it is further ensured that development of delamination is stopped at groove portion 24. Consequently, in the chip corner portion where delamination of the insulating film is likely, it is further ensured that delamination can be prevented from reaching the sealing ring.

In the chip corner portion, in many cases, delamination develops in such a shape as close to a right isosceles triangle, when a corner (chip corner) is assumed as a vertex when viewed two-dimensionally. In the first and second semiconductor devices in the present embodiment, even if such delamination develops, one side of two-dimensional shape of delamination can be made substantially in parallel to a direction in which the groove portion or the sealing ring extends, so that delamination can be prevented from reaching the sealing ring in a further ensured manner.

Referring to FIG. 11, in the third semiconductor device according to the present embodiment, groove portion 26 is discontinuously formed. By adopting this structure as well, development of delamination can be suppressed at groove portion 26. As delamination may occur in a discontinuous part of groove portion 26, a distance between groove portions 26 is preferably made as small as possible. Alternatively, a continuous groove portion is formed as in the first embodiment, and the groove portion preferably has a shape like a closed frame when viewed two-dimensionally.

As a function, an effect and the manufacturing method are otherwise the same as in the first embodiment, description thereof will not be repeated.

### Third Embodiment

Referring to FIGS. 14 to 19 and FIG. 7, a semiconductor device according to the third embodiment of the present invention will be described.

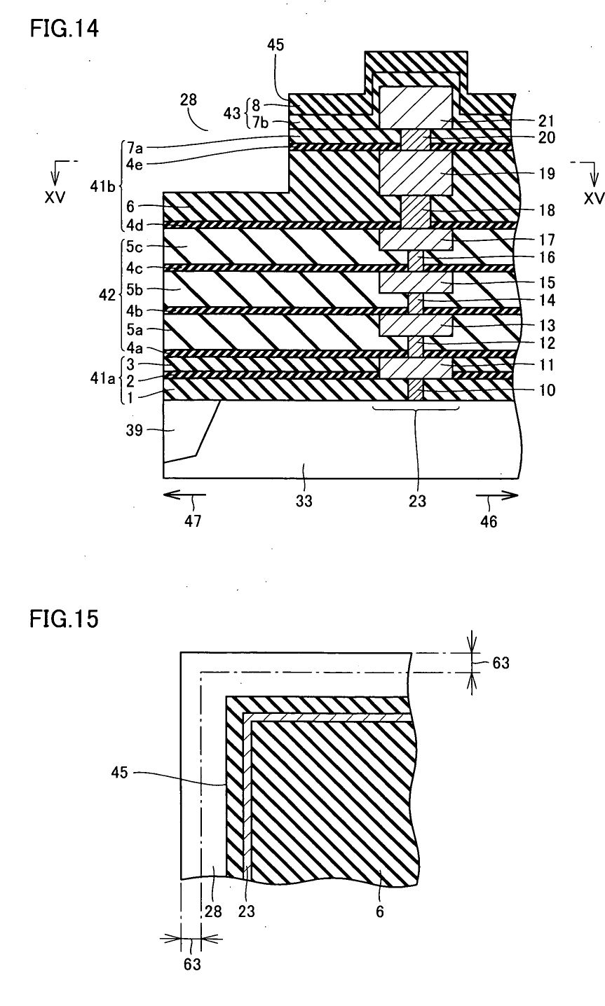

FIG. 14 is a schematic cross-sectional view of an end portion of the semiconductor device according to the present embodiment. The third embodiment is similar to the first embodiment in that stack structure 41a including the interlayer insulating film, stack structure 42 including the low dielectric constant film, stack structure 41b including the interlayer insulating film, and surface protection film 43 are formed in this order on the surface of silicon substrate 33. The third embodiment is similar to the first embodiment also in that sealing ring 23 is formed to surround the circuit forming region. Here, a direction shown with arrow 46 indicates the inner side of the semiconductor device, while a direction shown with arrow 47 indicates the outer side thereof.

In the semiconductor device according to the present embodiment, a cut portion 28 serving as the recessed portion is formed. Cut portion 28 is formed in such a manner that a part of the surface of the semiconductor device is cut outward. In the present embodiment, cut portion 28 is formed such that its cross-section is L-shaped. Cut portion 28 has a flat bottom portion.

Cut portion 28 is formed such that its bottom portion is located above low dielectric constant film 5c and below the upper end of copper interconnection 19 serving as the uppermost second copper interconnection. Cut portion 28 is formed to a depth below surface protection film 43, and formed such that the bottom portion is located within stack structure 41b including the interlayer insulating film. Cut portion 28 in the present embodiment is formed such that a distance between the bottom portion and low dielectric constant film 5c is set to at least 10 nm to at most 2 μm.

FIG. 15 shows a schematic cross-sectional view of a chip corner portion of the semiconductor device. FIG. 15 is a cross-sectional view in line XV-XV in FIG. 14 viewed in a direction of arrow. Sealing ring 23 in the present embodiment is formed in a substantially quadrangular shape when viewed two-dimensionally. Cut portion 28 is formed to surround sealing ring 23 along the same. Cut portion 28 is formed like a closed frame when viewed two-dimensionally. Cut portion 28 is formed such that an inner edge 45 thereof is substantially in parallel to sealing ring 23.

Arrow 63 indicates the dicing lane region. The dicing lane is set to extend along the side surface of the semiconductor device. Cut portion 28 is formed such that inner edge 45 thereof is arranged between the dicing lane in the region shown with arrow 63 and sealing ring 23 when viewed two-dimensionally. Cut portion 28 is formed to include the dicing lane. Cut portion 28 is formed such that inner edge 45 thereof is substantially in parallel to the dicing lane when viewed two-dimensionally.

As the structure is otherwise the same as in the first embodiment, description thereof will not be repeated.

Referring to FIG. 14, an effect that sealing ring 23 is formed like a wall surrounding the circuit forming region so that entry of water into the circuit forming region is prevented is the same as in the first embodiment.

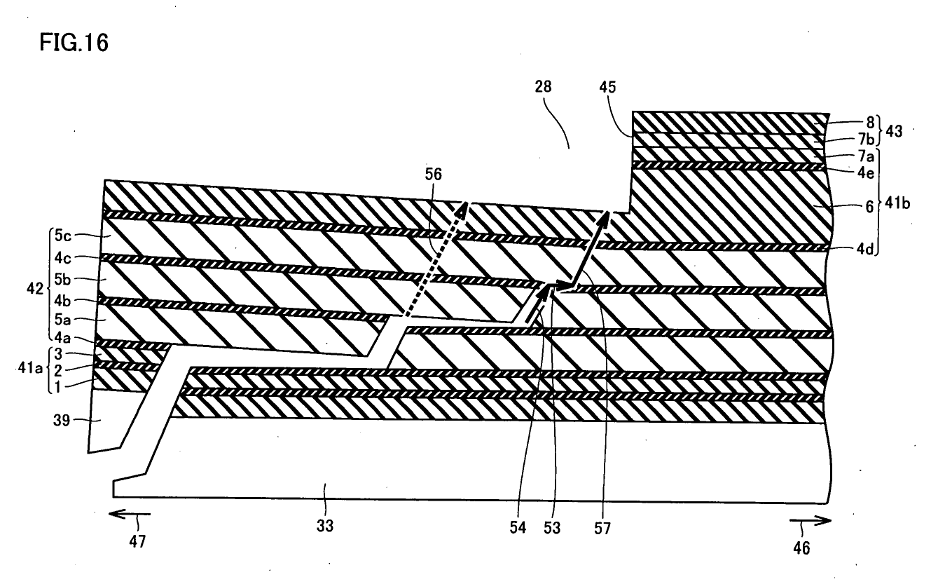

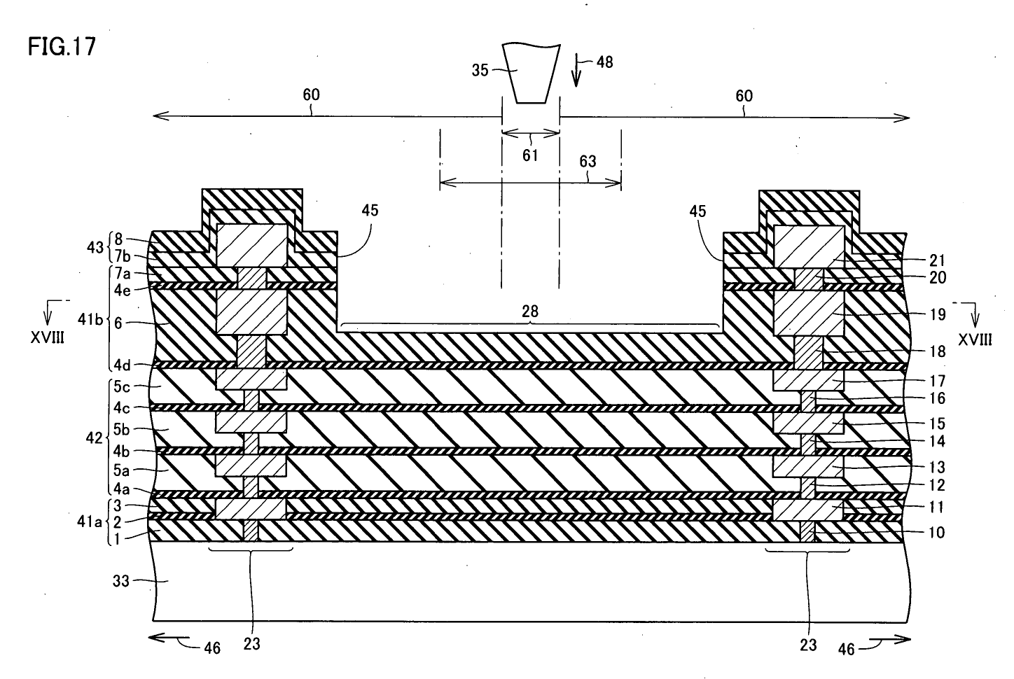

FIG. 16 is a schematic cross-sectional view for illustrating an effect of the semiconductor device according to the present embodiment. FIG. 16 is a schematic cross-sectional view of the end portion of the semiconductor device, without showing the sealing ring. Such a manner of delamination that delamination develops to the low dielectric constant film in the upper level toward the surface or develops in the lateral direction along the interface of the low dielectric constant film as a result of chipping 39 that occurred in silicon substrate 33 is the same as in the first embodiment.

In the present embodiment, as shown with arrows 53 and 54, delamination develops repeatedly to the layer above by one level and in the lateral direction along the interface, and thereafter, delamination is led to the region where cut portion 28 is formed, as shown with an arrow 57.

In the region directly under cut portion 28, silicon oxide film 6 has a small thickness. Therefore, as shown with arrow 56, delamination may reach the bottom surface of cut portion 28 in a position close to the end surface of the semiconductor device. As described above, in the present embodiment, delamination can be caused to reach the surface within the region where cut portion 28 is formed. Consequently, development in the lateral direction of delamination can be stopped within the region where cut portion 28 is formed, and delamination can be prevented from reaching sealing ring 23.

A semiconductor device according to the present embodiment was actually manufactured, and development of delamination of the low dielectric constant film was observed. The insulating film in the semiconductor device similar to that in the first semiconductor device in the first embodiment was employed, while cut portion 28 was formed instead of the groove portion. As to the depth of cut portion 28, a distance from low dielectric constant film 5c to the bottom portion of cut portion 28 was set to 1 μm. Largest development of delamination stopped at a position of inner edge 45 of cut portion 28. There was no example in which the delamination reached the sealing ring. Then, a moisture-resistance reliability test was conducted. There was no abnormality observed in an operation of an internal device, and excellent operation characteristic was exhibited.

Then, as in the first embodiment, a test for observing a maximum length of development of delamination was conducted with regard to various depths of the cut portion. The insulating film in the semiconductor device similar to that in the semiconductor device in the first embodiment used in the test with regard to various depths of the groove portion was employed, while cut portion 28 was formed instead of the groove portion.

FIG. 19 is a conceptual view of the end portion of the semiconductor device according to the present embodiment. In the present embodiment, a length from uppermost low dielectric constant film 36 in the stack structure including the low dielectric constant film to the bottom portion of cut portion 28 is denoted as x2. In addition, a length from low dielectric constant film 36 to the surface of surface protection film 43 in the region other than cut portion 28 and the sealing ring is denoted as y2. Length y2 was set to 3 μm as in the first embodiment. A length L2 from the end surface of the semiconductor device to inner edge 45 of cut portion 28 was set to 30 μm as in the first embodiment.

FIG. 7 shows the result of the test with regard to various depths of the cut portion. It can be seen that a distance of development of delamination is shorter, as length x2 is smaller. In addition, when length x2 was set to 2.5 μm, delamination extended beyond the region where the cut portion was formed, although delamination did not reach the sealing ring. Length x2 was set to 2 μm or smaller, so that development of delamination could be stopped at the region where the cut portion was formed.

Based on the result of the test, length x2 is preferably set to 2 μm or smaller as in the first embodiment. In addition, a ratio of length x2 to length y2 (x2/y2) is preferably set to ⅔ or smaller. Moreover, when length x2 was set to 0.5 μm or smaller (not larger than ⅙ of the distance between the low dielectric constant film and the surface of the surface protection film), the region where delamination occurred substantially coincided with the region where chipping of the silicon substrate occurred, when observed from above. Namely, delamination that occurred hardly developed in the lateral direction. As described above, the cut portion is formed and the thickness of the interlayer insulating film on the low dielectric constant film is made smaller, so that development of delamination toward the circuit forming region can be suppressed.

A width of the groove portion in the first embodiment is made larger, so that development in the lateral direction of delamination can further effectively be prevented as well. For example, if a width of the groove portion is made equal to or larger than a distance between the groove portion and the sealing ring (not smaller than 5 μm in the first embodiment), the distance between an outer end portion of the groove portion and the sealing ring in the direction of development of delamination can be twice or larger the distance between the inner edge of the groove portion and the sealing ring, and delamination can be led to the groove portion with further sufficient margin.

As the present embodiment is similar to the first embodiment in that the distance between the low dielectric constant film and the bottom portion of the cut portion is preferably set to 10 nm or larger and the inner edge of the cut portion is preferably formed substantially in parallel to the sealing ring, description thereof will not be repeated.

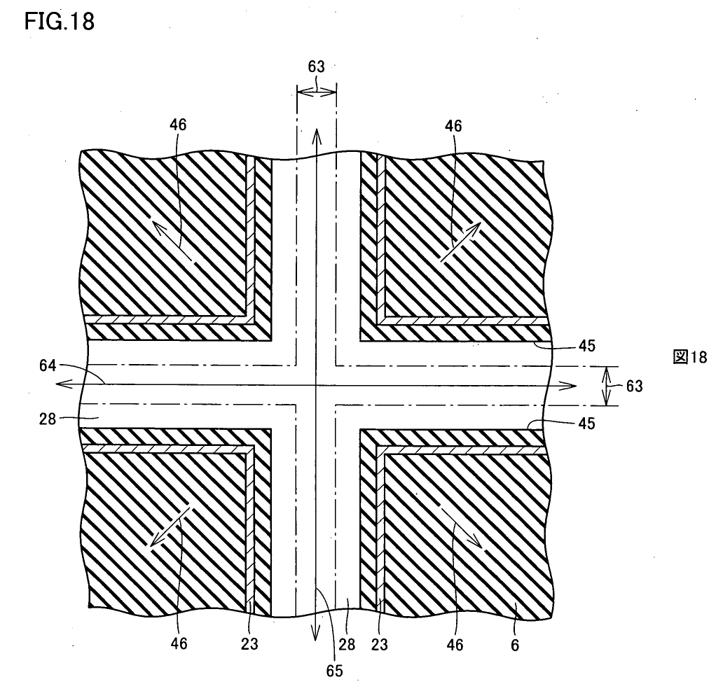

A dicing step in a method of manufacturing the semiconductor device according to the present embodiment will be described with reference to FIGS. 17 and 18.

FIG. 17 is a schematic cross-sectional view of a portion where two semiconductor devices face with each other among the plurality of semiconductor devices formed on the surface of silicon substrate 33. In the present embodiment, stack structures 41a, 41b, 42, and 43 are formed on the surface of silicon substrate 33, and thereafter the resist is disposed followed by etching, whereby cut portion 28 is formed. In the present embodiment, cut portion 28 is formed to a depth below protection film 43, and formed such that its bottom portion is located above low dielectric constant film 5c.

The region indicated with arrow 63 represents the dicing lane, while the region indicated with arrow 61 represents the region where dicing is actually performed. Dicing blade 35 is pressed against in a direction shown with arrow 48 while rotating, and carries out cutting into individual semiconductor devices.

In the present embodiment, cut portion 28 is formed to be larger than the dicing lane shown with arrow 63. Namely, when the semiconductor device is completed, cut portion 28 is formed such that inner edge 45 thereof is arranged on the inner side relative to the dicing lane. Inner edge 45 of the cut portion is arranged between the dicing lane and the sealing ring. By adopting such a structure, it is ensured that the cut portion remains in the semiconductor device in dicing.

FIG. 18 is a cross-sectional view in line XVIII-XVIII in FIG. 17 viewed in a direction of arrow. Cut portion 28 is formed like a line when viewed two-dimensionally. Cut portion 28 is formed along the perimeter of each semiconductor device to be formed. The region shown with arrow 63 represents the dicing lane region. Dicing is carried out in the directions shown with arrows 64 and 65.

In the present embodiment, though the cross-section of the cut portion is L-shaped, the present embodiment is not limited thereto and any shape may be employed. For example, the cross-section of the inner end portion of the cut portion may have an arc shape.

As a function, an effect and the manufacturing method are otherwise the same as in the first embodiment, description thereof will not be repeated.

### Fourth Embodiment

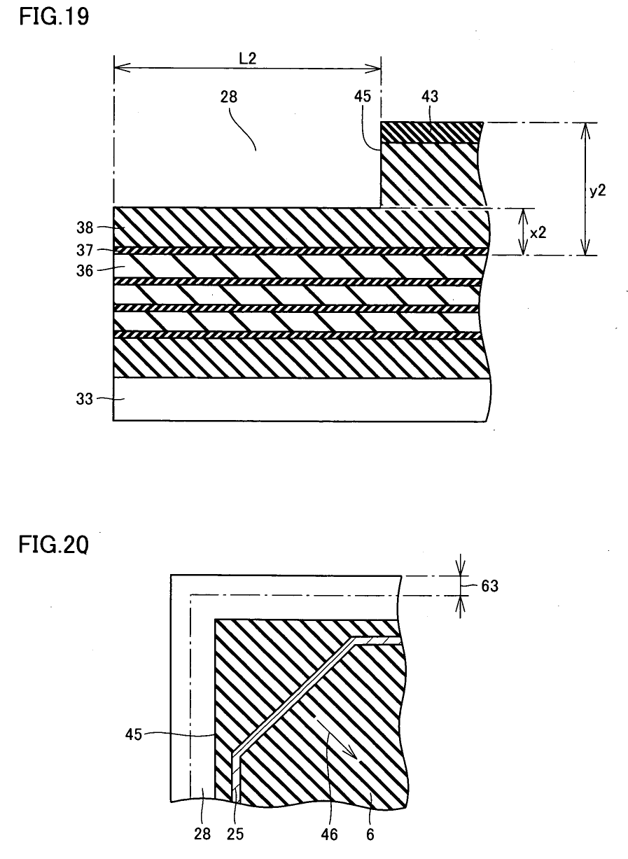

Referring to FIGS. 20 to 25, a semiconductor device according to the fourth embodiment of the present invention will be described.

FIG. 20 is a schematic cross-sectional view of a chip corner portion of a first semiconductor device according to the present embodiment. The fourth embodiment is similar to the third embodiment in that inner edge 45 of cut portion 28 is formed along the end portion of the semiconductor device or inner edge 45 is arranged between sealing ring 25 and the dicing lane shown with arrow 63 in the first semiconductor device.

In the first semiconductor device according to the present embodiment, sealing ring 25 has a corner beveled in the chip corner portion. Namely, sealing ring 25 is formed in a manner inclined with respect to a perimeter of the semiconductor device in the chip corner portion. Sealing ring 25 has a substantially octagonal shape when viewed two-dimensionally.

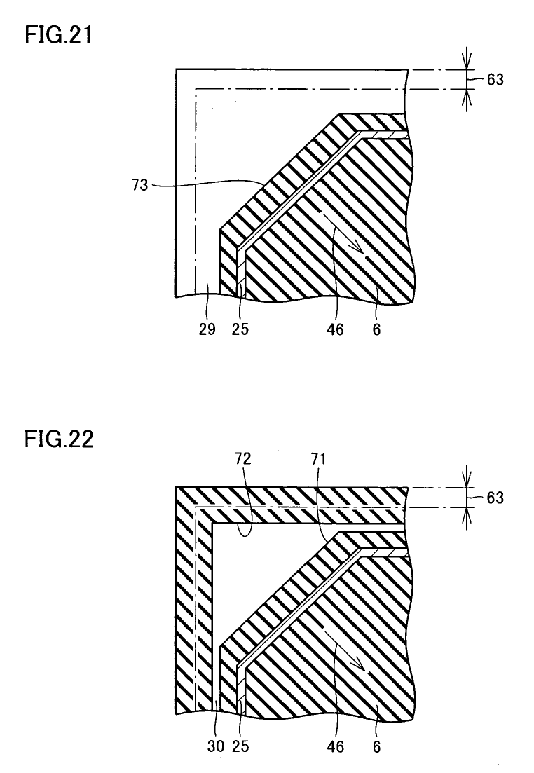

FIG. 21 is a schematic cross-sectional view of a chip corner portion of a second semiconductor device according to the present embodiment. In the second semiconductor device, sealing ring 25 is beveled in the chip corner portion and has a substantially octagonal shape. In addition, a cut portion 29 is formed such that an inner edge 73 thereof extends in a manner conforming to the shape of sealing ring 25. Namely, cut portion 29 is formed such that inner edge 73 thereof has a substantially octagonal two-dimensional shape. Cut portion 29 is formed to have a larger width in the chip corner portion, and formed like a line in a region other than the chip corner portion. Cut portion 29 is formed such that inner edge 73 thereof is arranged between sealing ring 25 and the dicing lane shown with arrow 63.

FIG. 22 is a schematic cross-sectional view of a chip corner portion of a third semiconductor device according to the present embodiment. The third semiconductor device includes sealing ring 25 having a corner beveled in the chip corner portion and having a substantially octagonal shape. A groove portion 30 is beveled such that an inner edge 71 thereof extends along sealing ring 25, and formed such that an outer edge 72 of groove portion 30 extends along the perimeter of the semiconductor device. Namely, groove portion 30 is formed such that inner edge 71 thereof has a substantially octagonal two-dimensional shape and such that outer edge 72 thereof has a substantially quadrangular two-dimensional shape.

In the third semiconductor device, groove portion 30 is formed to have a larger width in the chip corner portion. Groove portion 30 is formed to have a substantially triangular two-dimensional shape in the chip corner portion. In a region other than the chip corner portion, groove portion 30 is formed like a line when viewed two-dimensionally. Groove portion 30 is formed between the dicing lane shown with arrow 63 and sealing ring 25.

As the structure is otherwise the same as in the first to third embodiments, description thereof will not be repeated.

Referring to FIG. 20, in the first semiconductor device according to the present embodiment, sealing ring 25 is beveled in the chip corner portion.

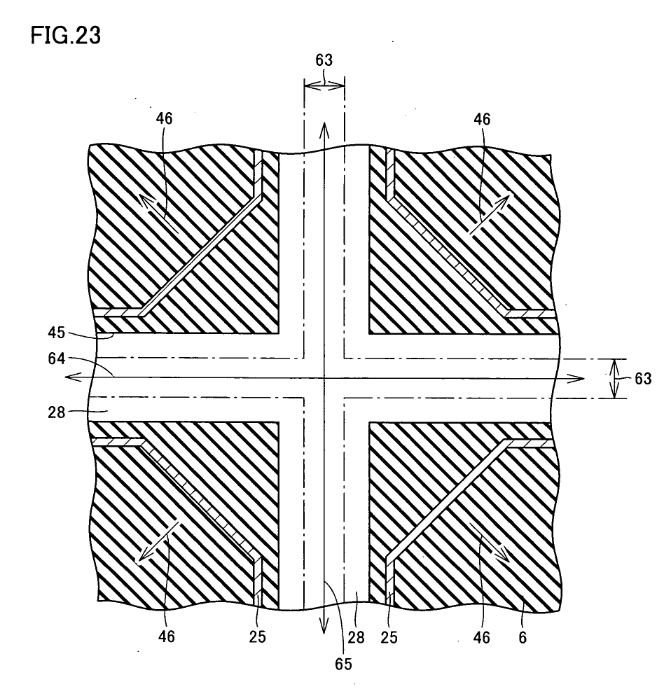

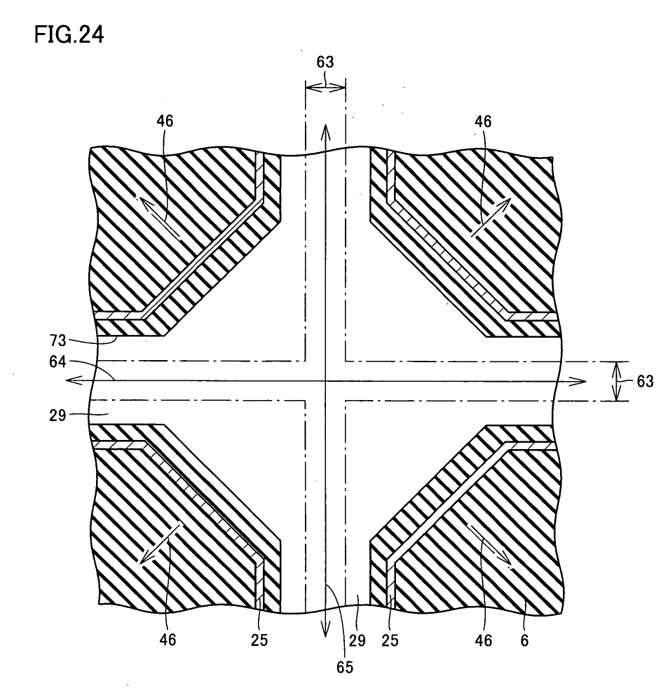

FIG. 23 is a schematic cross-sectional view for illustrating a dicing step in a method of manufacturing the first semiconductor device according to the present embodiment. Arrow 63 indicates the dicing lane region, while arrow 46 shows the inner side of the semiconductor device. The dicing lane is included within cut portion 28.

In manufacturing the semiconductor device, sealing ring 25 is formed such that its two-dimensional shape is substantially octagonal. In addition, cut portion 28 is formed like a line. Cut portion 28 is formed such that inner edge 45 thereof is located between the dicing lane and sealing ring 25. In dicing, as shown with arrows 64 and 65, the dicing blade is moved in directions orthogonal to each other, for cutting into individual semiconductor chips.

Sealing ring 25 is beveled in the chip corner portion, so that a distance between the corner and sealing ring 25 can be made larger in the chip corner portion and delamination can be prevented from reaching sealing ring 25 in a more ensured manner.

Referring to FIG. 21, in the second semiconductor device in the present embodiment, sealing ring 25 is beveled in the chip corner portion and inner edge 73 of cut portion 29 is formed along sealing ring 25. Cut portion 29 is formed to have a larger width in the chip corner portion.

FIG. 24 is a schematic cross-sectional view for illustrating a dicing step in a method of manufacturing the second semiconductor device according to the present embodiment. Cut portion 29 is formed to include the dicing lanes orthogonal to each other. Cut portion 29 is formed such that inner edge 73 thereof extends in a manner conforming to the shape of sealing ring 25. One semiconductor device is formed such that cut portion 29 and sealing ring 25 have a substantially octagonal shape. Dicing is performed in directions of arrows 64 and 65.

Cut portion 29 is formed to have a larger width in the chip corner portion, so that an area of the region where the cut portion is formed and hence an area for leading delamination toward the cut portion are made larger. Consequently, it is further ensured that delamination is led to the cut portion. As described previously, delamination of the insulating film is likely in the chip corner portion, and delamination develops in a two-dimensionally triangular shape. It is further ensured that such delamination can also be prevented from reaching the sealing ring.

Referring to FIG. 22, in the third semiconductor device according to the present embodiment, sealing ring 25 is beveled in the chip corner portion. Groove portion 30 is formed such that inner edge 71 thereof extends substantially in parallel to sealing ring 25 and such that outer edge 72 of groove portion 30 extends substantially in parallel to the perimeter of the semiconductor device.

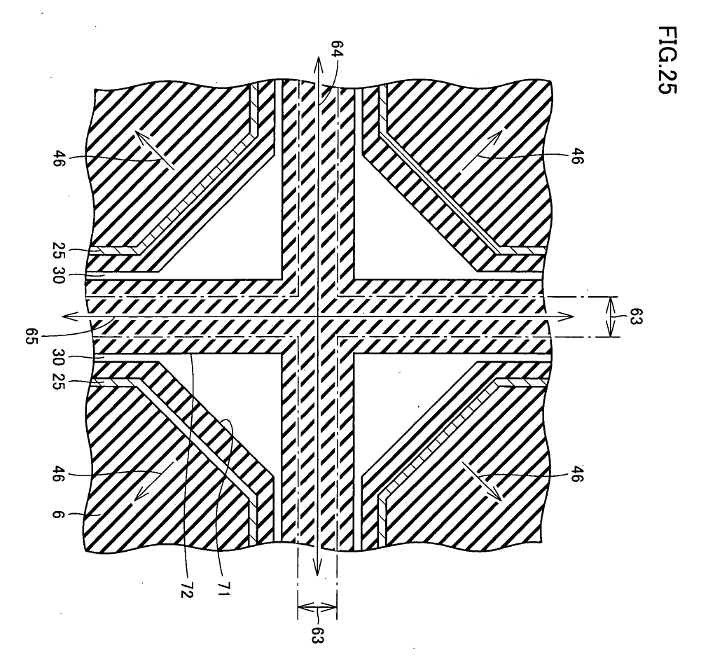

FIG. 25 shows a schematic cross-sectional view for illustrating a dicing step in a method of manufacturing the third semiconductor device according to the present embodiment. Groove portion 30 is formed such that inner edge 71 thereof extends in a manner conforming to the shape of sealing ring 25 in the chip corner portion. Groove portion 30 is formed such that outer edge 72 thereof extends substantially in parallel to the perimeter of the semiconductor device to be formed. Groove portion 30 is thus formed to have a larger width in the chip corner portion. Dicing is performed in directions of arrows 64 and 65.

Groove portion 30 is formed to have a larger width in the chip corner portion, so that an area of groove portion 30 can be made larger in the chip corner portion. Consequently, an effect similar to that of the cut portion can be obtained in the chip corner portion. Namely, delamination develops toward the bottom portion of the groove portion, and delamination can be led to the bottom portion of the groove portion in a position more distant from the sealing ring.

As a function, an effect and the manufacturing method are otherwise the same as in the first to third embodiments, description thereof will not be repeated.

It is noted that the “upper” side and the “lower” side in the present invention do not refer to an absolute up-down direction (vertical direction), and merely refer to relative positional relation of a device or a film. In addition, the lateral direction refers to a direction perpendicular to the up-down direction.

According to the present invention, a semiconductor device of which productivity is high and in which development of delamination as far as the sealing ring is prevented can be provided.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A semiconductor device, comprising:
a substrate;
a low dielectric constant film arranged above the substrate, that has a first copper interconnection formed therein and has a relative dielectric constant of at most 3.3;
an interlayer insulating film arranged above said low dielectric constant film;
a surface protection film arranged above said interlayer insulating film;
a sealing ring formed to surround a circuit forming region; and
a recessed portion formed outside said sealing ring when viewed two-dimensionally; wherein
at least one layer in said interlayer insulating film includes a second copper interconnection therein,
at least one layer in said interlayer insulating film and said surface protection film has a Young's modulus larger than said low dielectric constant film,
said recessed portion includes at least one of a groove portion and a cut portion,
said recessed portion is formed such that its bottom portion is located above said low dielectric constant film, and
said recessed portion is formed such that said bottom portion is located below an upper end of uppermost said second copper interconnection.

2. The semiconductor device according to claim 1, wherein
said recessed portion is formed such that a distance between said bottom portion and said low dielectric constant film is set to at least 10 nm to at most 2 μm.

3. The semiconductor device according to claim 1, wherein
x/y is set to at most ⅔, where x represents the distance between said low dielectric constant film and said bottom portion and y represents a distance between said low dielectric constant film and a surface of said surface protection film in a region other than a region where said recessed portion or said sealing ring is formed.

4. The semiconductor device according to claim 1, wherein
said recessed portion is formed in a shape of a closed frame when viewed two-dimensionally.

5. The semiconductor device according to claim 1, wherein
said recessed portion is formed such that an inner edge thereof is arranged between a dicing lane and said sealing ring, when viewed two-dimensionally.

6. The semiconductor device according to claim 1, wherein
said recessed portion is formed such that at least a part of an inner edge thereof is substantially in parallel to a dicing lane, when viewed two-dimensionally.

7. The semiconductor device according to claim 1, wherein
said recessed portion is formed such that at least a part of an inner edge thereof is substantially in parallel to said sealing ring, when viewed two-dimensionally.

8. The semiconductor device according to claim 1, further comprising a chip corner portion serving as a corner when viewed two-dimensionally, wherein
said recessed portion is formed such that its width is greater in said chip corner portion when viewed two-dimensionally.

9. A semiconductor device, comprising:
a substrate;
a low dielectric constant film arranged above the substrate and having a relative dielectric constant of at most 3.3;
an interlayer insulating film arranged above said low dielectric constant film;
a surface protection film arranged above said interlayer insulating film;
a sealing ring formed to surround a circuit forming region; and
a recessed portion formed outside said sealing ring when viewed two-dimensionally; wherein
at least one layer in said interlayer insulating film and said surface protection film has a Young's modulus larger than said low dielectric constant film,
said recessed portion includes at least one of a groove portion and a cut portion, and
said recessed portion is formed to have a depth below said surface protection film and formed such that its bottom portion is located at a depth between said surface protection film and said low dielectric constant film.

10. The semiconductor device according to claim 9, wherein
said recessed portion is formed such that a distance between said bottom portion and said low dielectric constant film is set to at least 10 nm to at most 2 μm.

11. The semiconductor device according to claim 9, wherein
x/y is set to at most ⅔, where x represents the distance between said low dielectric constant film and said bottom portion and y represents a distance between said low dielectric constant film and a surface of said surface protection film in a region other than a region where said recessed portion or said sealing ring is formed.

12. The semiconductor device according to claim 9, wherein
said recessed portion is formed in a shape of a closed frame when viewed two-dimensionally.

13. The semiconductor device according to claim 9, wherein
said recessed portion is formed such that an inner edge thereof is arranged between a dicing lane and said sealing ring, when viewed two-dimensionally.

14. The semiconductor device according to claim 9, wherein
said recessed portion is formed such that at least a part of an inner edge thereof is substantially in parallel to a dicing lane, when viewed two-dimensionally.

15. The semiconductor device according to claim 9, wherein
said recessed portion is formed such that at least a part of an inner edge thereof is substantially in parallel to said sealing ring, when viewed two-dimensionally.

16. The semiconductor device according to claim 9, further comprising a chip corner portion serving as a corner when viewed two-dimensionally, wherein
said recessed portion is formed such that its width is greater in said chip corner portion when viewed two-dimensionally.
